(19) United States
(12) Patent Application Publication
(10) Pub. No.: US 2006/0289953 A1
(43) Pub. Date: Dec. 28, 2006

(54) Semiconductor device and manufacturing method of the same

(76) Inventors: Kiwamu Sakuma, Yokohama-shi (JP); Yoshinori Tsuchiya, Yokohama-shi (JP); Masato Koyama, Miura-gun (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/390,288

(22) Filed: Mar. 28, 2006

(30) Foreign Application Priority Data
Jun. 27, 2005 (JP) P2005-187037

(51) Int. Cl. H01L 29/94

(52) U.S. Cl. 257/412

(57) ABSTRACT

A semiconductor device includes a first semiconductor layer of a first conductivity type, a first gate insulating film, a first gate electrode and first source/drain regions. The first gate insulating film is formed on the first semiconductor layer. The first gate electrode is formed on the first gate insulating film. The first gate electrode includes crystal grains of a first metal consisting of Ru, and a second metal selected from the group consisting of W, Ni, Mo, Rh, Pd, Re Ir, and Pt. The second metal is segregated at a grain boundary between the crystal grains of the first metal. The first source/drain regions are formed in the first semiconductor layer, across the first gate insulating film from each other in a gate length direction of the first gate insulating film.

### CROSS-REFERENCE TO RELATED APPLICATIONS

This application is based upon and claims the benefit of priority from the Japanese Patent Application No. 2005-187037 filed on Jun. 27, 2005; the entire contents of which are incorporated herein by reference.

### BACKGROUND OF THE INVENTION

1. Field of the Invention

The invention relates to a semiconductor device having a field-effect transistor and a manufacturing method of the same.

2. Description of the Related Art

The silicon ULSI is one of the base technologies that will support a future society of highly advanced information technologies. To increase functionality of integrated circuits, it is necessary to increase performance of constituent semiconductor devices such as MOSFET (metal-oxide-semiconductor field-effect transistor) and the CMOSFET (complementary MOSFET). The device performance has been increased basically according to the proportional reduction rules. In recent years, however, various physical limitations have come to make it difficult to increase the device performance by ultra-miniaturization.

For example, as for a gate electrode using a compound semiconductor, problems—that gate parasitic resistance is exposed due to increase in device operation speed, effective insulating film capacitance decreases due to carrier depletion at the insulating film interface, and threshold voltages vary due to penetration of a doped impurity into the channel region—have been pointed out. Metal gate electrode materials have been proposed to solve these problems.

In particular, since Ru, Ir, Pt and Re have high heat resistance and their effective work functions can be adjusted to values (4.8 to 5.2 eV) around the top of the valence band of Si, which are compatible with p⁺ polysilicon, Ru, Ir, Pt and Re well match current processes that require devices to be heat resistant up to 1,000° C. Therefore, Ru, Ir, Pt and Re are considered promising candidates for a metal gate electrode material for the p-channel MOSFET.

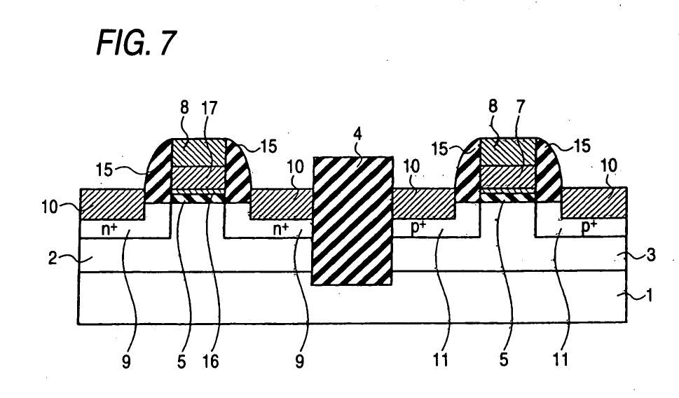

However, there is a report that points out a problem that in the case of a single Ru layer, for example, oxygen diffuses through the Ru layer during high-temperature heat treatment, resulting in increase of the thickness of the gate insulating film (SiO₂ film). For example, an SiO₂ film having a thickness of 3 nm originally is increased to 3.8 nm after being subjected to heat treatment at 900° C. for 30 seconds (See Z. Chen et al., “Stability of Ru- and Ta-based Metal Gate Electrode in Contact with Dielectrics for Si-CMOS,” Phys. Stat. Sol. (b) 241, No. 10, 2004, p. 2,253; FIG. 7(a)). The 0.8-nm increase in film thickness caused by the heat treatment is very influential in future-generation MOSFETs because their gate insulating films are as very thin as 1 nm or less. Also, in the case of an HfO₂, the thickness of an interface SiO₂ layer at the HfO₂/Si interface increases after heat treatment at 400° C. for 30 minutes (see R. Jha et al., “Evaluation of Fermi Level Pinning in Low, Midgap and High Workfunction Metal Gate Electrodes on ALD and MOCVD HfO₂ under High Temperature Exposure,” IEDM Tech. Dig., 2004, p. 295).

For the above reasons, where Ru is used in a gate electrode, no MOSFET could be manufactured that is superior in heat resistance.

### BRIEF SUMMARY OF THE INVENTION

Under the above circumstances, the invention has been made and provides a semiconductor device, which is superior in heat resistance, and a manufacturing method of the semiconductor device.

According to one aspect of the invention, a semiconductor device includes a first semiconductor layer of a first conductivity type, a first gate insulating film, a first gate electrode and first source/drain regions. The first gate insulating film is formed on the first semiconductor layer. The first gate electrode is formed on the first gate insulating film. The first gate electrode includes crystal grains of a first metal consisting of Ru, and a second metal selected from the group consisting of W, Ni, Mo, Rh, Pd, Re Ir, and Pt. The second metal is segregated at a grain boundary between the crystal grains of the first metal. The first source/drain regions are formed in the first semiconductor layer, across the first gate insulating film from each other in a gate length direction of the first gate insulating film.

According to another aspect of the invention, a semiconductor device includes a first semiconductor layer of a first conductivity type, a first gate insulating film, a first gate electrode and first source/drain regions. The first gate insulating film is formed on the first semiconductor layer. The first gate electrode is formed on the first gate insulating film. The first gate electrode includes crystal grains of a first metal consisting of Pt, and a second metal selected from the group consisting of W, Re, Rh, Pd, Ir, and Ru. The second metal is segregated at a grain boundary between the crystal grains of the first metal. The first source/drain regions are formed in the first semiconductor layer, across the first gate insulating film from each other in a gate length direction of the first gate insulating film.

According to a still another aspect of the invention, a semiconductor device includes a first semiconductor layer of a first conductivity type, a first gate insulating film, a first gate electrode and first source/drain regions. The first gate insulating film is formed on the first semiconductor layer. The first gate electrode is formed on the first gate insulating film. The first gate electrode includes crystal grains of a first metal consisting of Ir, and a second metal selected from the group consisting of Re, Rh, Ni, Pd, Pt and Ru. The second metal is segregated at a grain boundary between the crystal grains of the first metal. The first source/drain regions are formed in the first semiconductor layer, across the first gate insulating film from each other in a gate length direction of the first gate insulating film.

According to a still another aspect of the invention, a semiconductor device includes a first semiconductor layer of a first conductivity type, a first gate insulating film, a first gate electrode and first source/drain regions. The first gate insulating film is formed on the first semiconductor layer. The first gate electrode is formed on the first gate insulating film. Te first gate electrode includes crystal grains of a first metal consisting of Re, and a second metal selected from the group consisting of Rh, Ni, Pd, Ir, Pt and Ru. The second metal is segregated at a grain boundary between the crystal grains of the first metal. The first source/drain regions are formed in the first semiconductor layer, across the first gate insulating film from each other in a gate length direction of the first gate insulating film.

According to a still another aspect of the invention, a method for manufacturing a semiconductor device, includes: forming a first gate insulating film on a first semiconductor layer of a first conductivity type; and forming a first gate electrode on the first gate insulating film. The first gate electrode includes a layer having crystal grains of a first metal consisting of Ru, and a layer having a second metal selected from the group consisting of W, Ni, Mo, Rh, Pd, Re, Ir, and Pt. The method further includes: segregating the second metal at a grain boundary between the crystal grains of the first metal; and forming first source/drain regions in the first semiconductor layer, across the first gate insulating film from each other in a gate length direction of the first gate insulating film.

According to the above described structure and configuration, a semiconductor device having a very thin insulating film as well as its manufacturing method can be achieved.

### BRIEF DESCRIPTION OF THE INVENTION

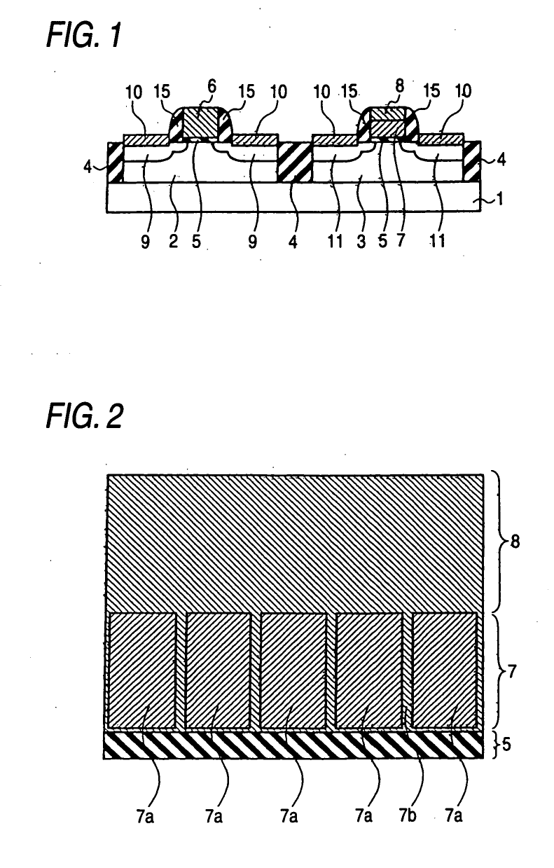

FIG. 1 is a schematic sectional view of an exemplary CMOSFET according to a first embodiment taken along a gate length direction.

FIG. 2 is an enlarged schematic sectional view of part of a gate electrode of a p-MOSFET according to the first embodiment.

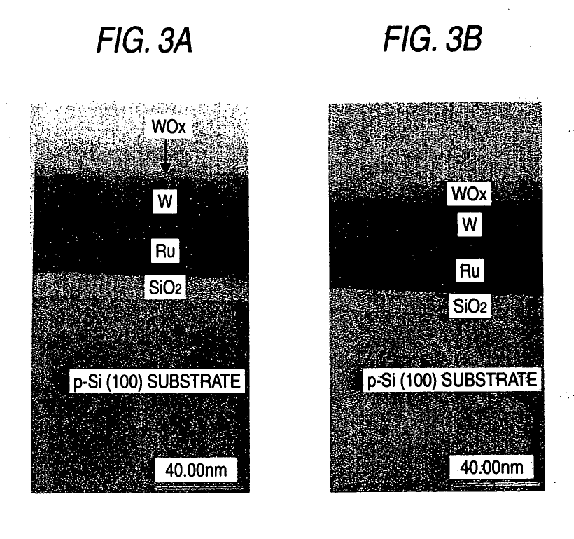

FIG. 3 is TEM images (cross sections) taken after the gate electrode of the p-MOSFET according to the first embodiment was subjected to heat treatment processes.

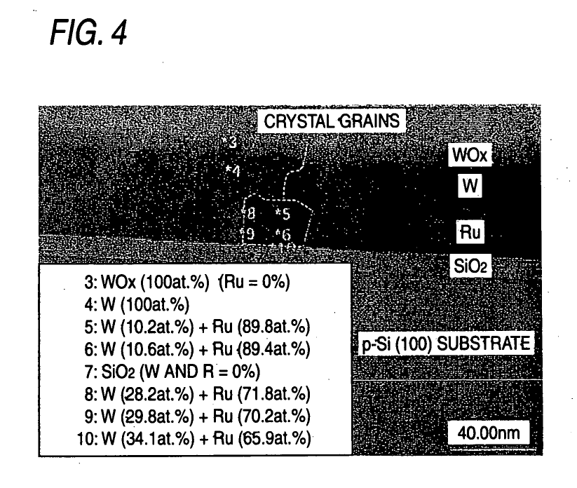

FIG. 4 is a TEM image (cross section) taken after the gate electrode of the p-MOSFET according to the first embodiment was subjected to heat treatment at 1,000° C. and a table showing compositions obtained by an EDX analysis, at respective points in the TEM image.

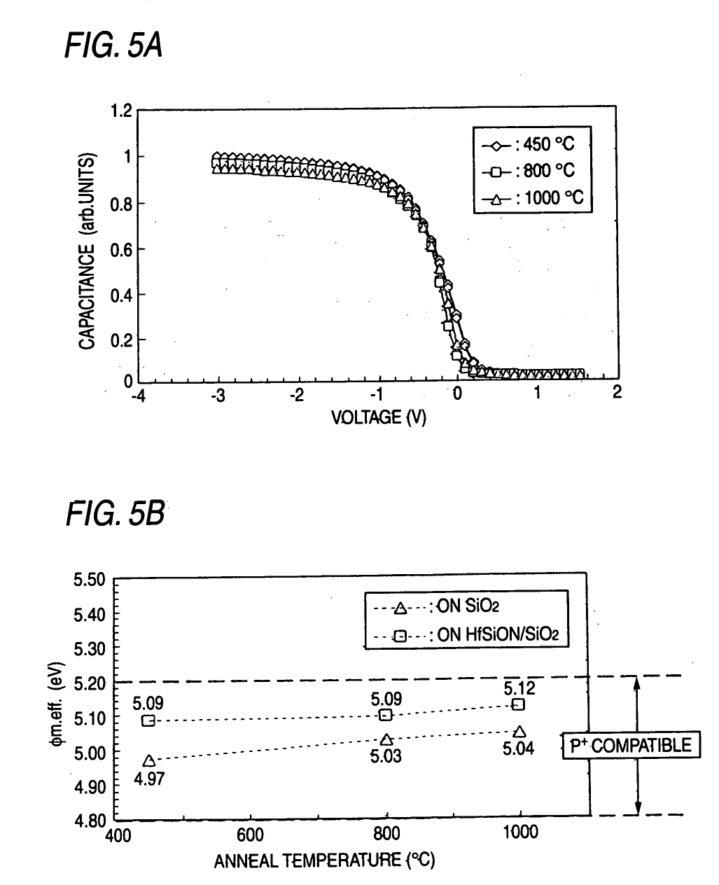

FIG. 5A is a graph showing how C-V curve varies depending on the temperatures of the heat treatment performed on the gate electrode of the p-MOSFET according to the first embodiment, and FIG. 5B shows work function values of the gate electrode of the p-MOSFET according to the first embodiment.

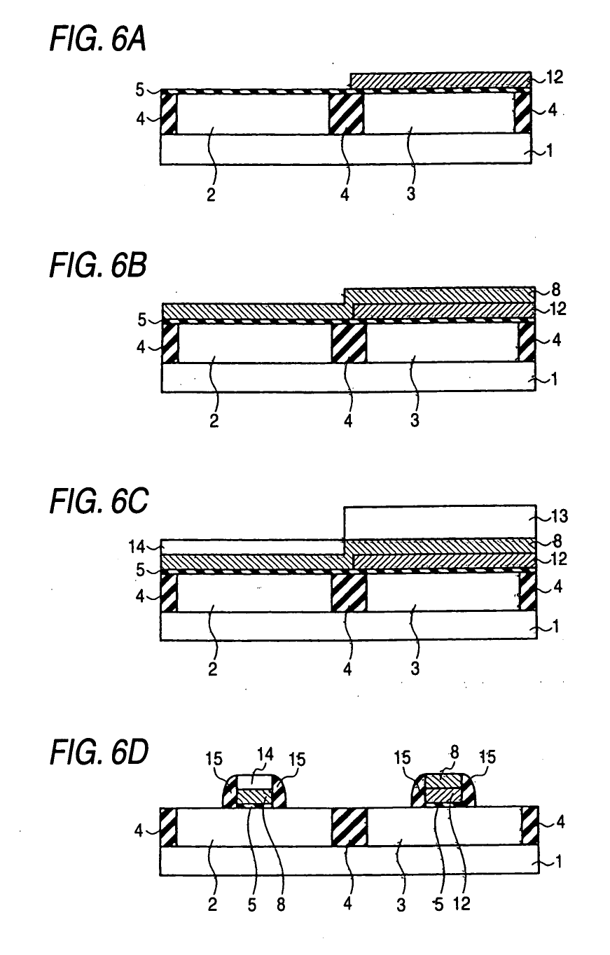

FIG. 6 is schematic sectional views showing an exemplary manufacturing method of the CMOSFET according to the first embodiment, taken along the gate length direction.

FIG. 7 is schematic sectional views of an exemplary MOSFET according to a modification of the first embodiment taken along the gate length direction.

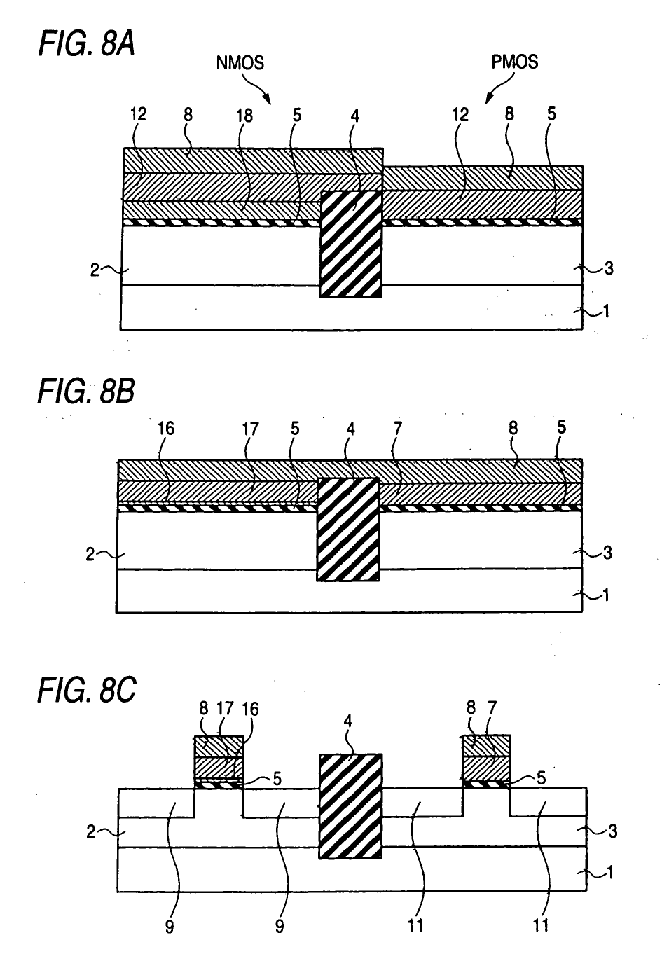

FIG. 8 is schematic sectional views showing an exemplary manufacturing method of the CMOSFET according to the first embodiment taken along the gate length direction.

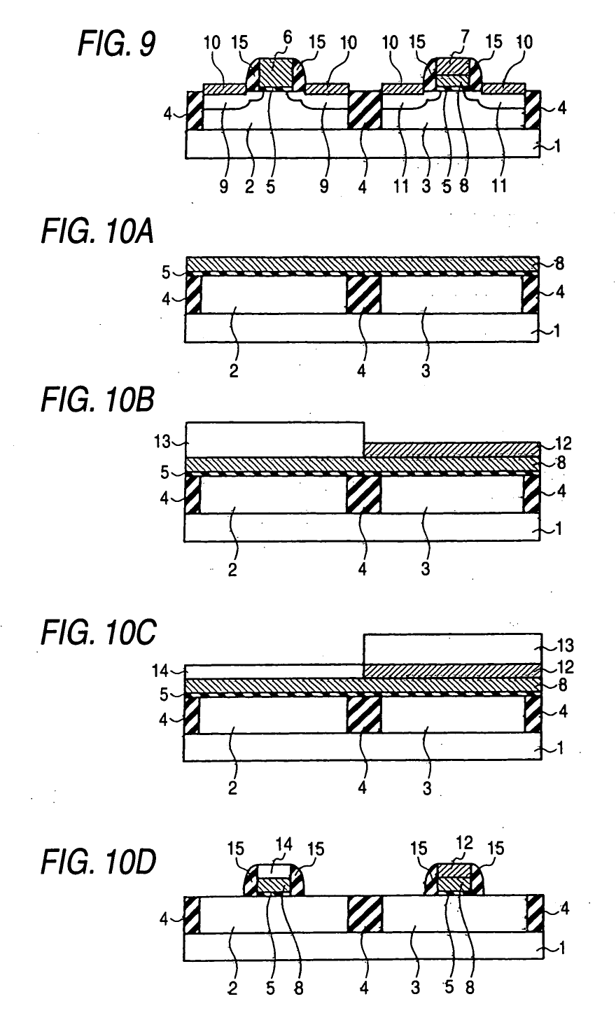

FIG. 9 is a schematic sectional view of an exemplary CMOSFET according to a second embodiment taken along the gate length direction.

FIG. 10 is schematic sectional views showing an exemplary manufacturing method of the CMOSFET according to the second embodiment taken along the gate length direction.

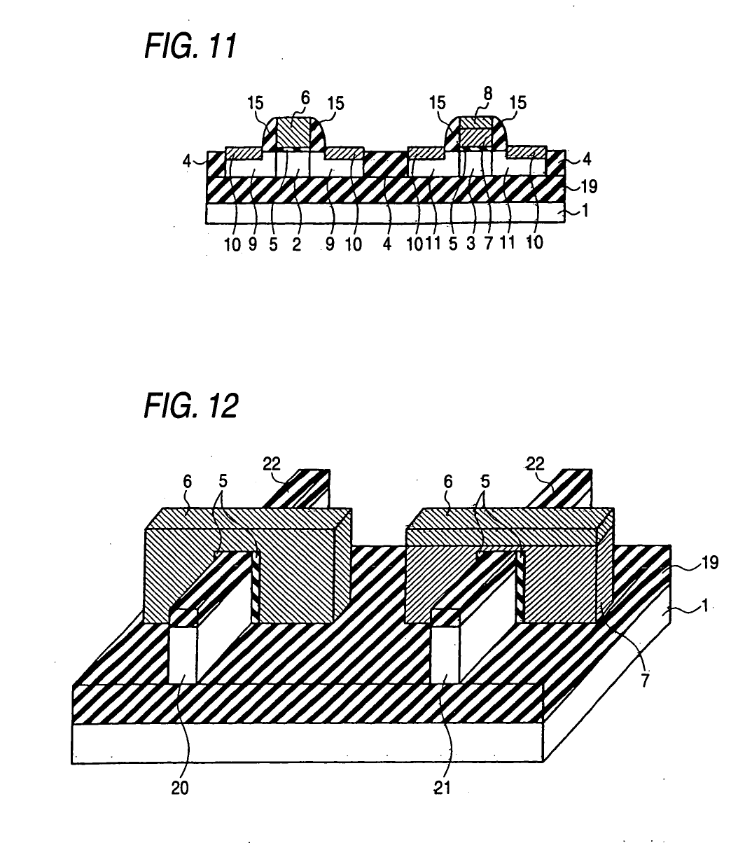

FIG. 11 is a schematic sectional view of an exemplary CMOSFET according to a third embodiment taken along the gate length direction.

FIG. 12 is a schematic sectional view of an exemplary CMOSFET according to a fourth embodiment taken along the gate length direction.

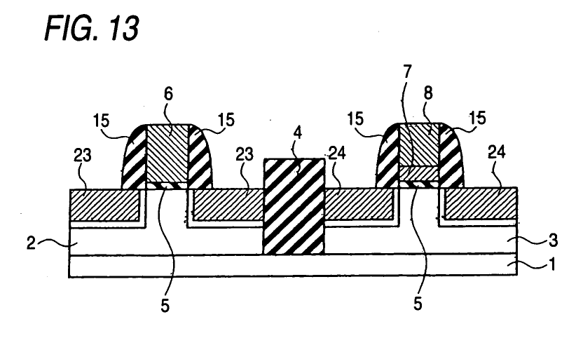

FIG. 13 is a schematic sectional view of an exemplary CMOSFET according to a fifth embodiment taken along the gate length direction.

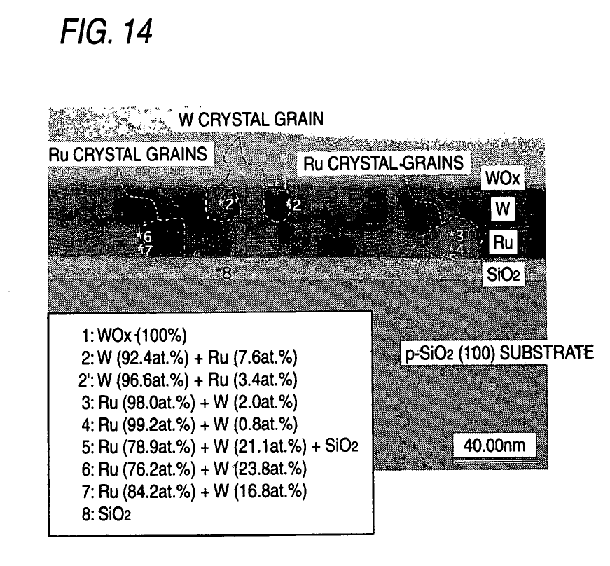

FIG. 14 is a TEM image (cross section) taken after the gate electrode of the p-MOSFET according to the first embodiment was subjected to heat treatment at 800° C. and a table showing compositions obtained by an EDX analysis, at respective points in the TEM image.

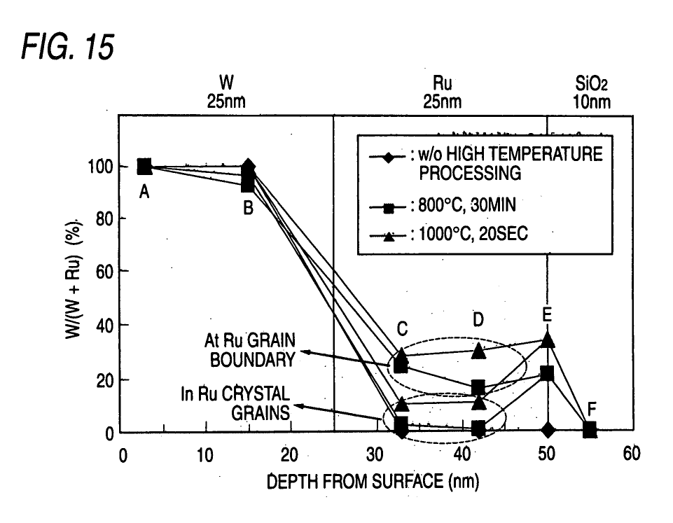

FIG. 15 is a graph showing a relation between a composition ratio of W and depth from a surface of a gate electrode.

### DETAILED DESCRIPTION OF EMBODIMENTS OF THE INVENTION

Embodiments of the invention will be hereinafter described with reference to the drawings. The same structures will be given the same reference signs throughout the embodiments and will not be described redundantly. The drawings are schematic ones that are drawn for convenience of description and intended to facilitate its understanding. The shapes, dimensions, ratios, etc. of the structures shown in the respective drawings may be different from those of actual devices, and may be modified as appropriate with the following description and the prior art taken into consideration.

Although each embodiment will be directed to a CMOSFET whose gate insulating film is made of an oxide, naturally each embodiment may likewise be applied to a p-MOSFET alone. Also, the material of the gate insulating film is not limited to an oxide. Each embodiment may likewise be applied to a MISFET whose gate insulating film is made of another kind of insulator such as a nitride or a fluoride.

Further, each embodiment may likewise be applied to PROMs such as an EPROM (erasable programmable read-only memory), an EEPROM (electrically erasable programmable ROM), and a flash memory.

Still further, the scope of the invention includes a memory, a logic circuit, etc. formed by integrating semiconductor devices as mentioned above as well as a system LSI etc. in which they are mounted on a single chip.

### First Embodiment

An exemplary CMOSFET according to a first embodiment will be described below with reference to FIG. 1.

FIG. 1 is a schematic sectional view of an exemplary CMOSFET according to the first embodiment, taken along the gate length direction.

As shown in FIG. 1, a p-type semiconductor layer 2 and an n-type semiconductor layer 3 are formed on a semiconductor substrate 1. An n-MOSFET is formed on the p-type semiconductor layer 2 and a p-MOSFET is formed on the n-type semiconductor layer 3. A device isolation layer 4 is formed between the n-MOSFET and the p-MOSFET. Operating complementarily, the n-MOSFET and the p-MOSFET constitute a CMOSFET.

First, the n-MOSFET will be described. A gate insulating film 5 is formed on the upper surface of the p-type semiconductor layer 2, and a WSiₓ layer 6 functioning as a gate electrode is formed on the gate insulating film 5. Gate side walls 15 are formed on both sides, in the gate length direction, of the gate insulating film 5 and the WSiₓ layer 6. First source/drain regions 9 are formed on both sides, in the gate length direction, of a channel region formed in the upper surface of the p-type semiconductor layer 2 immediately under the gate insulating film 5. The first source/drain regions 9 has extension regions that are located on both sides, in the gate length direction, of the channel region and diffusion layers that are located on both sides, in the gate length direction, of the extension layers and are deeper than the extension layers. Contact electrodes 10 made of NiSiₓ are formed on the respective first source/drain regions 9.

Next, the p-MOSFET will be described. A gate insulating film 5 is formed on the upper surface of the n-type semiconductor layer 3. A layer 7 (functioning as first layer) having Ru crystal grains and W that is segregated at Ru grain boundaries is formed on the gate insulating film 5, and a W layer 8 (functioning as a second layer) is formed on the first layer 7. Gate side walls 15 are formed on both sides, in the gate length direction, of the gate insulating film 5, the first layer 7, and the second layer 8. Second source/drain regions 11 and contact electrodes 10 are formed in the p-MOSFET 7 in the same manners as the first source/drain regions 9 and the contact electrodes 10 of the n-MOSFET.

Next, the configuration of the CMOSFET according to the first embodiment will be described in detail.

The material of the gate insulating films 5 may be a material selected as appropriate as being necessary for a transistor of each generation. More specifically, silicon oxide or an insulating film material (high-permittivity dielectric) having higher permittivity than silicon oxide is used. Examples of the high-permittivity dielectric insulating film material include Si₃N₄, Al₂O₃, Ta₂O₅, TiO₂, La₂O₅, CeO₂, ZrO₂, HfO₂, SrTiO₃, and Pr₂O₃. Materials like Zr silicate and Hf silicate in which a metal ion is mixed into silicon oxide may be used, and combinations of those materials may also be used.

No limitations are imposed on the thickness of the gate insulating films 5, and each gate insulating film 5 may be one or more mono-layers. To minimize reduction in gate capacitance, it is necessary that the gate insulating films 5 be as thin as possible. Specifically, it is desirable that the thickness of the gate insulating films 5 be 2 nm or less in terms of the SiO₂ equivalent thickness.

To minimize the sheet resistance that depends on the aspect ratio of the gate electrode height and the gate electrode length, the gate electrode height needs to be not very great. In generations in which the gate electrode length is shorter than or equal to 30 nm, it is desirable that the height of each gate electrode be smaller than or equal to 50 nm.

The source/drain regions 9 and 11 may have, in addition to a combination of a shallow junction and a deep junction as a high-concentration impurity diffusion, a structure selected as appropriate as being necessary for a transistor of each generation (e.g., a silicide layer). Also in the following embodiments, unless otherwise specified, naturally the structure described therein may be replaced with a necessary one.

Examples of the material of the contact electrodes 10, in addition to NiSiₓ, include various silicides of V, Cr, Mn, Y, Mo, Ru, Rh, Hf, Ta, W, Ir, Co, Ti, Er, Pt, Pd, Zr, Gd, Dy, Ho, and Er.

The gate electrode material of the n-MOSFET may have low resistivity (50 μΩ·cm or less) and such heat resistance as to be able to withstand source/drain impurity activation heat treatment (about 1,000° C.). A specific example is WSiₓ (work function: 4.3 eV). It is known that the work function of a metal material depends on the crystal face: in general, even in the same substance, a crystal face having a lower atomic density exhibits a smaller work function. For example, the (113) plane and the (116) plane of W exhibit work functions 4.18 eV and 4.3 eV, respectively.

The first layer 7 of the gate electrode of the p-MOSFET will be described in more detail with reference to FIG. 2.

FIG. 2 is an enlarged schematic sectional view of part of the gate electrode of the p-MOSFET according to the first embodiment.

As shown in FIG. 2, the first layer 7 is a Ru polycrystalline layer in which W 7b is segregated at grain boundaries between Ru crystal grains 7a. The second layer 8 is a single crystal layer, a polycrystalline layer, or an amorphous layer of W.

It is considered that the above structure is formed in such a manner that in heat treatment described later W in the second layer 8 diffuses through the grain boundaries and reaches the interface between the gate insulating film 5 and the first layer 7. Based on the following measurement results, it is considered that W that is segregated at the Ru grain boundaries prevents oxygen from passing therethrough and thereby prevents the gate insulating film 5 from being increased in thickness.

Next, various measurement results of the p-MOSFET according to the first embodiment will be described with reference to FIGS. 3 to 5.

FIG. 3 is TEM images (cross sections) taken after the gate electrode of the p-MOSFET according to the first embodiment was subjected to heat treatment. It is noted that the gate electrode is examined using the p-MOS capacitor.

FIGS. 3A and 3B are TEM images (cross sections) taken after heat treatment at 450° C. and heat treatment at 1,000° C. were performed, respectively. As shown in FIGS. 3A and 3B, a p-Si (100) substrate, an SiO₂ film (10 nm), a Ru layer (25 nm), a W layer (25 nm), and a WOₓ layer are laid one on another in this order. As shown in FIGS. 3A and 3B, no thickness increase of the SiO₂ film was found in the vicinities of the Ru grain boundaries after either of the heat treatment at 450° C. and the heat treatment at 1,000° C. and the thickness of the SiO₂ film remained 10 nm (i.e., the thickness did not vary) after each of the heat treatment at 450° C. and the heat treatment at 1,000° C. It is therefore concluded that thickness of the SiO₂ film was not increased even by the heat treatment at 1,000° C.

FIG. 4 is a TEM image (cross section) taken after the gate electrode of the p-MOSFET according to the first embodiment was subjected to heat treatment at 1,000° C. for 20 seconds in Ar atmosphere and a table showing composition ratios obtained by an EDX analysis, at respective points in the image. The composition ratios were derived only from a ratio between a first metal (Ru) and a second metal (W). In particular, the components of the insulating film (SiO₂ film) are omitted in determining the composition at point 10, which is in contact with the insulating film.

The measurement conditions of FIG. 4 are as follows.

Transmission electron microscope (TEM): HF-2000 (manufactured by Hitachi, Ltd.)

Acceleration voltage: 200 kV

Beam diameter: about 1 nm

Elemental analysis (EDX) instrument: Noran Voyager IIIM3100

Energy resolution: 137 eV

Measurement time: 30 sec

As shown in FIG. 4, the composition at point 4 in the second layer 8 includes only W. In the first layer 7, the composition ratio of W at points 8, 9, and 10 at the boundary between the Ru crystal grain were higher than those at points 5 and 6 in the Ru crystal grain. The ratio of W was particularly high at point 10, which was located at the interface between the first layer 7 and the gate insulating film 5.

The above result shows that W in the second layer 8 diffuses into the first layer 7 but Ru in the first layer 7 does not diffuse into the second layer 8. It is also understood that the main diffusion paths of W are Ru grain boundaries. Further, the fact that W also exists at the interface between the gate insulating film 5 and the first layer 7 shows that diffused W reaches the interface between the gate insulating film 5 and the first layer 7.

It is known that both of Ru and W do not form stable compounds at least up to 1,600° C., and no such compounds were found in the above measurement. It is therefore considered that metal W is segregated at the grain boundaries of metal Ru.

FIG. 14 is a TEM image (cross section) taken after the gate electrode of the p-MOSFET according to the first embodiment was subjected to heat treatment at 800° C. for 30 minutes in Ar atmosphere and a table showing composition ratios obtained by an EDX analysis, at respective points in the image. The composition ratios were obtained in a similar manner to those for the heat treatment at 1,000° C. The measurement conditions of FIG. 14 are the same as those of FIG. 4.

FIG. 15 is a graph showing a relation between the composition ratio of W and depth from the surface of the gate electrode. Diamond marks in FIG. 15 represent measurement results of the gate electrode, which has been subjected to the heat treatment at 450° C. in Ar atmosphere. The diamond marks in FIG. 15 show that no W exist in the second layer 7 (Ru layer) or the gate insulating film (SiO₂ layer). In other words, the heat treatment at 450° C. does not diffuse W into the Ru layer or the SiO₂ layer.

Triangle marks shown in FIG. 15 represent measurement results of the gate electrode, which has been subjected to the heat treatment at 1,000° C. for 20 seconds in Ar atmosphere. With regard to the heat treatment at 1,000° C., the following table shows a relation between the points 3 to 10 in FIG. 4 and points A to F in FIG. 15.

| | | W (at. %) |
|---|---|---|
| 3 | A | 100 |
| 4 | B | 100 |
| 5 | C (in Ru crystal grains) | 10.2 |
| 8 | C (at Ru grain boudanry) | 28.2 |
| 6 | D (in Ru crystal grains) | 10.6 |
| 9 | D (at Ru grain boudanry) | 28.2 |
| 10 | E | 29.8 |
| 7 | F | 0 |

Square marks shown in FIG. 15 represent measurement results of the gate electrode, which has been subjected to the heat treatment at 800° C. for 30 minutes in Ar atmosphere. With regard to the heat treatment at 800° C., the following table shows a relation between the points 1, 2, 2′ and 3 to 8 in FIG. 14 and point A to F in FIG. 15.

| | | W (at. %) |
|---|---|---|
| 1 | A | 100 |
| 2, 2′ | B | 92.4, 96.6 |
| 3 | C (in Ru crystal grains) | 2 |
| 6 | C (at Ru grain boudanry) | 23.8 |
| 4 | D (in Ru crystal grains) | 0.8 |
| 7 | D (at Ru grain boudanry) | 16.8 |
| 5 | E | 21.1 |
| 8 | F | 0 |

It is apparent from FIG. 15 that as in the case of the heat treatment 1,000° C., the heat treatment at 800° C. diffuses W of the second layer 8 into the first layer 7 and that as a result of the diffusion, W reaches the boundary between the first layer 7 and the gate insulating film 1 (SiO₂) . On the other hand, the heat treatment at 450° C. does not diffuse W. Accordingly, it is preferable that the gate electrode according to this embodiment is heat at 500° C. or more from the view point of diffusing W from the second layer 8 to the first layer 7.

Also, it is apparent from FIG. 15 that no W diffuses into the gate insulating film 1 (see point F in FIG. 15). The inventors further made a comparison experiment in which an SiO₂ layer was formed on a p-SiO₂ substrate, a Ru layer was formed on the SiO₂ layer and then the thus-obtained structure is heated at 1,000° C. for 20 seconds in Ar atmosphere. It is noted that no W layer was formed on the Ru layer in the comparison experiment. The result of the comparison experiment showed that Ru diffused into the SiO₂ layer. Although the measurement result of the heat treatment at 1,000° C. does not show that Ru diffuses into the SiO₂ layer, there is fear that heating at 1,000° C. may diffuse Ru diffuse from the Ru layer (first layer 7) into the SiO₂ (the gate insulating film 1) as in the comparison experiment. Furthermore, comparing the triangle marks and the square marks at points C and D in FIG. 15, we can see that the heat treatment at 1,000° C. diffused more W than that at 450° C. On the other hand, a roughness of the uppermost surface of the gate electrode (the surface of WOₓ layer), which had been subjected to the heat treatment at 1,000° C., became higher than its original roughness. Therefore, it is considered that since a large amount of W diffused from the second layer 8, the surface of the second layer 8 (WOₓ layer) became rougher. There is a fear that if W in a certain portion of the second layer 8 is depleted because of the diffusion of a large amount of W from the certain portion, the surface of the second layer 8 (WOₓ layer) above the certain portion may be concave to form an opening, a part of the first layer 7 (Ru layer) may be exposed through the opening, and then oxygen may diffuse into the first layer 7 (Ru layer) through the opening. Accordingly, it is preferable that the gate electrode according to this embodiment is heat at 950° C. or less from the viewpoint of (i) surely preventing Ru from diffusing into the gate insulating film and (ii) preventing depletion of W in the second layer 8.

Furthermore, the heat treatment of the gate electrode according to this embodiment may be performed in a range of 750° C. to 850° C. If the heating temperature is less than 750° C., the heat treatment takes longer time. Also, if the heating temperature is higher than 850° C., it would be hard to ensure the process margin.

The heat treatment at 800° C. for 30 minutes in Ar atmosphere (FIG. 14 and the square marks in FIG. 15) falls in the range of 500° C. to 950° C. From the viewpoint of avoiding the depletion of W in the first layer 8, it is preferable that the composition ratio of W in the Ru crystal grains (e.g., points 3, 4 in FIG. 14 and points C, D in FIG. 15) is equal to or less than 5%, and may be equal to or less than 2%.

FIG. 5A is a graph showing how the C-V curve varies depending on the temperature of the heat treatment performed on the gate electrode of the MOSFET according to the first embodiment. SiO₂ film having 4 nm in thickness was used as a gate insulating film. Capacitance was measured after heat treatment processes at 450° C., 800° C., and 1,000° C.

It is seen from FIG. 5A that the maximum capacitance is the same for all the heat treatment processes, which means that the thickness of the SiO₂ film did not vary.

FIG. 5B shows work functions of the gate electrode of the p-MOSFET according to the first embodiment. The insulating film was an SiO₂ film and an HfSiON/SiO₂ stack film (HfSiON was adjacent to the gate electrode). Work functions were measured after heat treatment processes at 450° C., 800° C., and 1,000° C.

The work functions obtained with the SiO₂ film and the HfSiON/SiO₂ stack film are approximately the same. It is seen that the work function is not influenced by the heat treatment processes at up to 1,000° C. Further, all the work functions obtained are p⁺-polysilicon-compatible (4.8 to 5.2 eV) and are suitable for the gate electrode of the p-MOSFET.

The first embodiment can provide a CMOSFET that is superior in heat resistance because the thickness of the gate insulating films 5 is not increased by heat treatment. It is considered that this is because W that is segregated at Ru grain boundaries blocks oxygen diffusion paths.

It has been confirmed that the CMOSFET according to the first embodiment is heat resistant up to the source/drain impurity activation heat treatment temperature (usually 1,000° C.). Therefore, the manufacturing method of the MOSFET according to this embodiment well matches current manufacturing processes.

Although the above description has been made with the assumption that the metal that forms crystal grains in the first layer 7 is Ru and the metal that is the element for forming the second layer 8 and is segregated at Ru grain boundaries is W, the above description also applies to other combinations. In the following description, the metal that forms crystal grains in the first layer 7 will be referred to as “first metal” and the metal that is an element for forming the second layer 8 and is segregated at grain boundaries of the first metal will be referred to as “second metal.”

First, material properties of candidates for the first metal will be compared with each other with reference to Table 1.

TABLE 1
Material properties of candidates for first metal

| | | | Diffusion coefficient | Diffusion coefficient |
|---|---|---|---|---|
| | | Resistivity | (in Si, at 1,000° C.) | (in SiO₂, at 1,000° C.) |
| Material | Work function [eV] | [μΩ · cm] | [cm²/sec] | [cm²/sec] |
| Ru | 4.71 | 6.7 | 5 × 10⁻⁷-5 × 10⁻⁶ | More than 10⁻¹² |
| Ir | 5.0-5.8 | 4.7 | 3.1 × 10⁻⁷ | More than 10⁻¹² |
| Pt | 5.1-5.9 | 9.8 | 1.8 × 10⁻⁷ | More than 10⁻¹⁶ |
| Re | 4.72 | 19.3 | No data | No data |

As seen from Table 1, Ir is preferable from the viewpoint of low resistivity and Pt is preferable in terms of a small diffusion coefficient in an insulating film. Further, Ru is preferable from the viewpoint of the easiness of film formation by CVD, which is used in current processes.

Candidates for the second metal in the case where Ru is employed as the first metal will be described below with reference to Table 2.

TABLE 2
Maximum heat treatment temperatures and material properties of candidates
for second metal in the case where Ru is employed as first metal

| | Maximum heat | | | Diffusion coefficient | Diffusion coefficient |
|---|---|---|---|---|---|
| | treatment temp. | Work function | Resistivity | (in Si, at 1,000° C.) | (in SiO₂, at 1,000° C.) |
| Material | [° C.] | [eV] | [μΩ · cm] | [cm²/sec] | [cm²/sec] |
| W | 1,667 (compound formation) | 4.3-5.2 | 5 | 1.9 × 10⁻¹⁴ | Less than 10⁻²⁰ |
| Mo | 1,143 (compound formation) | 4.4-5.0 | 5 | Less than 1.0 × 10⁻¹¹ | Less than 10⁻²⁰ |
| Re | 2,334 (melting point of Ru) | 4.72 | 19.3 | No data | No data |
| Rh | 1,963 (melting point of Rh) | 4.98 | 4.3 | No data | No data |
| Ni | 1,455 (melting point of Ni) | 5.0-5.4 | 6.8 | 2.8 × 10⁻⁵ | 10⁻¹⁴-10⁻¹⁵ |
| Pd | 1,555 (melting point of Pd) | 5.2-5.6 | i | No data | No data |
| | | | 9.9 | | |
| Ir | 2,334 (melting point of Ru) | 5.0-5.8 | 4.7 | 3.1 × 10⁻⁷ | More than 10⁻¹² |
| Pt | 1,769 (melting point of Pt) | 5.1-5.9 | 9.8 | 1.8 × 10⁻⁷ | More than 10⁻¹⁶ |

Rh, Ir, W, and Mo are preferable from the viewpoint of making the gate electrode be low resistivity.

Ni, Ir, and Pt are preferable from the viewpoint of fast diffusion in Ru, resulting in reduction of the thermal budget of a heat treatment process for the diffusion of the second metal.

W and Mo, which do not tend to diffuse into an insulating film, are preferable from the viewpoint of preventing diffusion of Ru into the gate insulating film 5. It is also preferable that W or Mo be present on the gate insulating film 5.

W is preferable from the viewpoints of the easiness of film formation by CVD, which is used in current processes, and the easiness of execution of a CMOSFET manufacturing process (described later).

Based on the above discussion, it can be said that W is most preferable and Mo is second only to W as the second metal to be used together with the first metal Ru.

Candidates for the second metal in the case where Pt is employed as the first metal will be described below with reference to Table 3.

TABLE 3
Maximum heat treatment temperatures and material properties of candidates
for second metal in the case where Pt is employed as first metal

| | Maximum heat | | | Diffusion coefficient | Diffusion coefficient |
|---|---|---|---|---|---|
| | treatment temp. | Work function | Resistivity | (in Si, at 1,000° C.) | (in SiO₂, at 1,000° C.) |
| Material | [° C.] | [eV] | [μΩ · cm] | [cm²/sec] | [cm²/sec] |
| W | 1,769 (melting point of Pt) | 4.3-5.2 | 5 | 1.9 × 10⁻¹⁴ | Less than 10⁻²⁰ |
| Re | 1,769 (melting point of Pt) | 4.72 | 19.3 | No data | No data |
| Rh | 1,769 (melting point of Pt) | 4.98 | 4.3 | No data | No data |
| Pd | 1,555 (melting point of Pd) | 5.2-5.6 | 9.9 | No data | No data |
| Ir | 1,769 (melting point of Pt) | 5.0-5.8 | 4.7 | 3.1 × 10⁻⁷ | More than 10⁻¹² |
| Ru | 1,769 (melting point of Pt) | 4.71 | 6.7 | 5 × 10⁻⁷-5 × 10⁻⁶ | More than 10⁻¹² |

First, unlike Ru, Pt forms a compound with each of Mo and Ni at a low temperature. Therefore, it is not appropriate to use Mo or Ni as the second metal.

Rh, Ir, and W are preferable from the viewpoint of making the first gate electrode be low resistivity.

Ir and Ru are preferable from the viewpoint of fast diffusion in Pt, resulting in reduction of the thermal budget of a heat treatment process for the diffusion of the second metal.

W, which does not tend to diffuse into an insulating film, is preferable from the viewpoint of preventing diffusion of Pt into the gate insulating film 5. It is also preferable that W be present on the gate insulating film 5.

Ru and W are preferable from the viewpoint of the easiness of film formation by CVD, which is used in current processes.

W is preferable from the viewpoint of the easiness of execution of a CMOSFET manufacturing process (described later).

Based on the above discussion, it can be said that W is most preferable and Ru is second only to W as the second metal to be used together with the first metal Pt.

Candidates for the second metal in the case where Ir is employed as the first metal will be described below with reference to Table 4.

TABLE 4
Maximum heat treatment temperatures and material properties of candidates
for second metal in the case where Ir is employed as first metal

| | Maximum heat | | | Diffusion coefficient | Diffusion coefficient |
|---|---|---|---|---|---|
| | treatment temp. | Work function | Resistivity | (in Si, at 1,000° C.) | (in SiO₂, at 1,000° C.) |
| Material | [° C.] | [eV] | [μΩ · cm] | [cm²/sec] | [cm²/sec] |
| Re | 2,447 (melting point of Ir) | 4.72 | 19.3 | No data | No data |
| Rh | 1,963 (melting point of Rh) | 4.98 | 4.3 | No data | No data |
| Ni | 1,455 (melting point of Ni) | 5.0-5.4 | 6.8 | 2.8 × 10⁻⁵ | 10⁻¹⁴-10⁻¹⁵ |
| Pd | 1,555 (melting point of Pd) | 5.2-5.6 | 9.9 | No data | No data |
| Pt | 1,769 (melting point of Pt) | 5.1-5.9 | 9.8 | 1.8 × 10⁻⁷ | More than 10⁻¹⁶ |
| Ru | 2,334 (melting point of Ru) | 4.71 | 6.7 | 5 × 10⁻⁷-5 × 10⁻⁶ | More than 10⁻¹² |

First, unlike Ru, Ir forms a compound with each of W and Mo at a low temperature. Therefore, it is not appropriate to use W or Mo as the second metal.

Rh is preferable from the viewpoint of making the first gate electrode be low resistivity.

Ni, Pt, and Ru are preferable from the viewpoint of fast diffusion in Ir and resulting reduction of the thermal budget of a heat treatment process for the diffusion of the second metal.

Pt, which does not tend to diffuse into an insulating film, is preferable from the viewpoint of preventing diffusion of Ir into the gate insulating film 5. It is also preferable that Pt be present on the gate insulating film 5.

Ru is preferable from the viewpoint of the easiness of film formation by CVD, which is used in current processes.

Based on the above discussion, it can be said that Ru is most preferable and Pt is second only to Ru as the second metal to be used together with the first metal Ir.

Candidates for the second metal in the case where Re is employed as the first metal will be described below with reference to Table 5.

TABLE 5
Maximum heat treatment temperatures and material properties of candidates
for second metal in the case where Re is employed as first metal

| | Maximum heat | | | Diffusion coefficient | Diffusion coefficient |
|---|---|---|---|---|---|
| | treatment temp. | Work function | Resistivity | (in Si, at 1,000° C.) | (in SiO₂, at 1,000° C.) |
| Material | [° C.] | [eV] | [μΩ · cm] | [cm²/sec] | [cm²/sec] |
| Rh | 1,963 (melting point of Rh) | 4.98 | 4.3 | No data | No data |
| Ni | 1,455 (melting point of Ni) | 5.0-5.4 | 6.8 | 2.8 × 10⁻⁵ | 10⁻¹⁴-10⁻¹⁵ |
| Pd | 1,555 (melting point of Pd) | 5.2-5.6 | 9.9 | No data | No data |
| Ir | 2,447 (melting point of Ir) | 5.0-5.8 | 4.7 | 3.1 × 10⁻⁷ | More than 10⁻¹² |
| Pt | 1,769 (melting point of Pt) | 5.1-5.9 | 9.8 | 1.8 × 10⁻⁷ | More than 10⁻¹⁶ |
| Ru | 2,334 (melting point of Ru) | 4.71 | 6.7 | 5 × 10⁻⁷-5 × 10⁻⁶ | More than 10⁻¹² |

First, unlike Ru, Re forms a compound with each of W and Mo at a low temperature. Therefore, it is not appropriate to use W or Mo as the second metal.

Rh is preferable from the viewpoint of making the first gate electrode be low resistivity.

Ni, Ir, Pt, and Ru are preferable from the viewpoint of fast diffusion in Re, resulting in reduction of the thermal budget of a heat treatment process for the diffusion of the second metal.

Pt, which does not tend to diffuse into an insulating film, is preferable from the viewpoint of preventing diffusion of Re into the gate insulating film 5. It is also preferable that Pt be present on the gate insulating film 5.

Ru is preferable from the viewpoint of the easiness of film formation by CVD, which is used in current processes.

Based on the above discussion, it can be said that Ru is most preferable and Pt is second only to Ru as the second metal to be used together with the first metal Re.

Next, the CMOSFET according to the first embodiment will be described in more detail.

The thickness of the first layer 7 may be 1 to 50 nm. The thickness of the first layer 7 being greater than or equal to 1 nm enhances the effect of preventing the increase of the thickness of the gate insulating film 5. The thickness of the first layer 7 being smaller than or equal to 50 nm makes the second metal to reach the interface between the first layer 7 and the gate insulating film 5 easily. The thickness of the first layer 7 may be smaller than or equal to 25 nm. Also, the thickness of the first layer 7 may be smaller than or equal to 5 nm.

The size of crystal grains of the first metal may be 1 to 25 nm.

The size of crystal grains being larger than or equal to 1 nm enables formation of the first layer 7 with good film formation properties. The size of crystal grains being smaller than or equal to 25 nm makes it easier to provide at least two crystal grains within the gate lengths of future-generation CMOSFETs. Where at least two crystal grains are provided in the gate length direction, a larger number of grain boundaries extending in the film thickness direction exist. Therefore, the second metal can be provided on the gate insulating film 5 with a higher degree of uniformity. That is, from the viewpoint of securing a large number of grain boundaries extending in the film thickness direction, it is preferable that the size of crystal grains of the first metal be small. Specifically, the size of crystal grains of the first metal may be smaller than or equal to 25 nm. Furthermore, the size of crystal grains of the first metal may be smaller than or equal to 5 nm.

The composition ratio of the second metal in grain boundaries of the first metal may be 20 to 50 at. %. The composition ratio of the second metal being larger than or equal to 20 at. % enhances the effect of decreasing the degree of oxygen diffusion. If the composition ratio of the second metal exceeds 50 at. %, the effect of decreasing the degree of oxygen diffusion is lowered because the second metal being a single layer become dominant.

At grain boundaries between crystal grains of the first metal that are in contact with the gate insulating film 5, the composition ratio of the second metal may be larger than 0 at. %. Also, the composition ratio of the second metal may be 20 to 80 at. %. This is because the second metal having a large composition ratio can prevent oxygen diffusion into the gate insulating film 5 more reliably. Furthermore, the composition ratio of the second metal may be 50 to 80 at. %.

On the other hand, the composition ratio of the second metal in crystal grains of the first metal may be 0 to 20 at. %.

The above composition ratios are derived only from ratios between the first metal and the second metal. In particular, the components of the gate insulating film 5 are ignored in determining the composition rations at the positions that are in contact with the gate insulating film 5.

It is assumed that the ratio between the first metal and the second metal is measured by using the instruments mentioned in the description that has been made with reference to FIG. 4. However, the composition measuring method is not limited thereto.

The gate insulating film 5 may be of a single crystal or amorphous. This is because such a structure prevents the metal elements from diffusing from the first gate electrode. Examples of the material that is high in the ability to keep an amorphous state include HfON, HfSiON, HfAlON, and LaAlOₓ.

An exemplary manufacturing method of the CMOSFET according to the first embodiment will be described below with reference to FIG. 6.

First, device isolation layers 4 are formed selectively on a semiconductor substrate 1 by the STI (shallow trench isolation) method, the LOCOS (local oxidation of silicon) method, or the like.

Then, a p-type semiconductor layer (p-well) 2 and an n-type semiconductor layer (n-well) 3 are formed by ion implantation. A gate insulating film (silicon thermal oxidation film) 5 having 2 nm in thickness is formed on the surfaces of the p-type semiconductor layer 2, the n-type semiconductor layer 3, and the device isolation layers 4. Then, an Ru layer 12 is deposited by sputtering. The Ru layer 12 can also be deposited by a method other than sputtering, such as a CVD (chemical vapor deposition) method using such a gas as Ru(C₅H₅) ₂, Ru(dpm)3, Ru₃(CO) ₁₂, or Ru(C₅H₄C₂H₅) ₂. Although Ru, W, Si, etc. are deposited by sputtering in the following steps, CVD may be used unless otherwise specified. Damage to SiO₂ is lighter when CVD is used. Then, after patterning is performed by lithography, that portion of the Ru layer 12, which is located on the p-type semiconductor layer 2, is etched away by anisotropic etching to leave the Ru layer 12 only on the n-type semiconductor layer 3, whereby a structure of FIG. 6A is obtained.

Then, as shown in FIG. 6B, a W layer 8 is deposited by sputtering. Alternatively, a W layer 8 may be deposited by CVD using such a gas as W(CO)₆.

Then, only the n-type semiconductor layer 3 is covered with a hard mask 13 made of SiC, SiO₂, Si₃N₄, or the like and an Si layer 14 is deposited by sputtering, whereby a structure of FIG. 6C is obtained in which the Si layer 14 is left only on the p-type semiconductor layer 2. Alternatively, an Si layer 14 may be left only on the p-type semiconductor layer 2 by a method that part of a deposited Si layer 14 is removed by planarization such as CMP (chemical mechanical polishing) until the W layer 8 on the n-type semiconductor layer 3 appears.

Then, after patterning is performed, gate portions are formed by anisotropic etching. Then, portions to become shallow impurity diffusion layers of source/drain regions 9 and 11 of n-type and p-type MIS transistors are formed in a self-aligned manner by implanting arsenic and boron ions using the above lamination gates as masks. Subsequently, after gate side walls 15 are formed on the side surfaces of the lamination gates with an insulating material such as silicon oxide, portions to become deep impurity diffusion layers of the source/drain regions 9 and 11 are formed likewise by ion implantation using the gate side walls 15 as masks, whereby a structure of FIG. 6D is obtained.

Then, heat treatment at 800° C. is performed. As a result, in the p-MOSFET, W is diffused from the W layer 8 to the grain boundaries in the Ru layer 12, whereby a first layer 7 is formed in which W exists at the Ru grain boundaries. On the other hand, in the n-MOSFET, Si is diffused from the Si layer 14 to the W layer 8, whereby silicidation occurs and a WSiₓ layer 6 is formed. Since the heat treatment at 800° C. is performed before heat treatment at 1,000° C., which will be performed subsequently, it is possible to reliably prevent oxygen from diffusing into the gate insulating film 5 in the p-MOSFET and to decrease the resistance of the WSiₓ layer 6 in the n-MOSFET.

Then, heat treatment at 1,000° C. is performed, whereby the impurities are activated and source/drain regions 9 and 11 are formed. In this step, since the gate electrodes of the n-MOSFET and p-MOSFET are heat resistant up to 1,000° C., no change occurs which causes deterioration of the characteristics.

Then, a Ni layer having 20 nm in thickness is evaporated (sputtered) and heat treatment at 400° C. is performed, and non-reacted portions of the metal layer are etched away selectively. As a result, NiSi contact electrodes 10 are formed in a self-aligned manner only on the source/drain electrodes 9 and 11. The structure of FIG. 1 is thus obtained.

In general, where metal gate electrodes are used, because of their low heat resistance, replacement and a damascene process is indispensable and hence dummy gate formation and CMP is necessary. In contrast, according to the manufacturing method of this embodiment, since all of W, Ru, and Si materials are stable at high temperatures and thus capable of sustaining the source/drain activation heat treatment, the CMOSFET can be manufactured by the process that is similar to a process for a case of using polysilicon gate electrodes. That is, the simple conventional procedure can be employed in which gate electrodes are formed first and then source/drain diffusion regions are formed. This reduces the degree of complexity and the cost. Further, the problem of a damascene process that the surfaces of the channel regions and the gate insulating films of transistors are exposed again as topmost surfaces can be avoided, which incidentally prevents deterioration of the performance of the device itself and lowering of the reliability, which would be caused by the damascene process.

### Modification

A CMOSFET according to a modification of the first embodiment will be described below with reference to FIG. 7 (only differences from the first embodiment will be described).

As shown in FIG. 7, the gate electrode of the n-MOSFET has a lamination structure in which a thin W layer 16 having a thickness of 1 nm or less in thickness and being in contact with the gate insulating film 5, a Ru—Ta alloy layer 17, and a W layer 8 are stacked in this order from the bottom.

In the gate electrode of the n-MOSFET, the effective work function of the Ru—Ta alloy layer 17 is modulated (decreased) by a modulation effect of interface dipoles generated in the thin W layer 16. As a result, an effective work function of 4.3 eV or less, which is necessary for a low threshold voltage transistor, is realized.

A manufacturing method of the CMOSFET according to the modification of the first embodiment will be described below with reference to FIG. 8.

First, a device isolation layer 4 is formed on a semiconductor substrate 1 by the STI (shallow trench isolation) method.

Then, a p-type semiconductor layer (p-well) 2 and an n-type semiconductor layer (n-well) 3 are formed by ion implantation. A gate insulating film 5 (silicon thermal oxidation film) having 2 nm in thickness is formed on the surfaces of the p-type semiconductor layer 2, the n-type semiconductor layer 3, and the device isolation layer 4. Then, a Ta layer 18 is deposited by sputtering, and a portion of the Ta layer 18, which is located on the n-type semiconductor layer 3, is removed by lithography pattering. Subsequently, a Ru layer 12 and a W layer 8 are deposited by sputtering, whereby a structure of FIG. 8A is obtained.

Alternatively, each metal film may be deposited by CVD, which causes only light damage to the gate insulating film 5.

Then, heat treatment at 800° C. or higher is performed. As a result, in the p-MOSFET, W is diffused from the W layer 8 to the grain boundaries in the Ru layer 12, whereby a first layer 7 is formed in which W exists at the Ru grain boundaries. On the other hand, in the n-MOSFET, a Ru—Ta alloy layer 17 is formed by an interface solid phase reaction between the Ta layer 18 and the Ru layer 12. At the same time, a very small amount of W is diffused from the top W layer 8 through the grain boundaries of the Ru—Ta alloy layer 17 and reaches the interface between the gate insulating film 5 and the Ru—Ta alloy layer 17, whereby a thin W layer 16 is formed (see FIG. 8B).

The above process utilizes the following facts. In a W/Ta lamination structure, W cannot diffuse through the Ta film and hence cannot be introduced into the interface with the gate insulating film. In contrast, as to Ta—Ru alloy, Ru contained in the film promotes diffusion of W through grain boundaries and hence W is diffused to the interface with the gate insulating film. In general, when a Ru—Ta alloy layer is formed, Ta silicide is formed at the interface with the gate insulating film if the Ta layer is the bottom layer. In contrast, in this modification, the thin W layer 16, which is formed by diffusing W to the interface, suppresses this silicifying reaction. As a result, the heat resistance of the Ru—Ta alloy layer 17 is increased.

Then, patterning is performed and gate portions are formed by anisotropic etching (see FIG. 8C).

Then, portions to become shallow impurity diffusion layers of source/drain regions 9 and 11 of n-type and p-type MIS transistors are formed in a self-aligned manner by implanting arsenic and boron ions using the above lamination gates as masks. Subsequently, after gate side walls 15 are formed on the side surfaces of the lamination gates with an insulating material such as silicon oxide, portions to become deep impurity diffusion layers of the source/drain regions 9 and 11 are formed likewise by ion implantation using the gate side walls 15 as masks. Subsequently, a Ni layer having 20 nm in thickness is evaporated (sputtered) and heat treatment at 400° C. is performed. Non-reacted portions of the metal layer are etched away selectively. As a result, NiSi contact electrodes 10 are formed in a self-aligned manner only on the source/drain electrodes 9 and 11. The structure of FIG. 7 is thus obtained.

This modification provides the same advantages as the first embodiment because all of W, Ru, and Ta are stable at high temperatures and thus capable of sustaining the source/drain activation heat treatment.

### Second Embodiment

A CMOSFET according to a second embodiment will be described below with reference to FIG. 9 (only differences from the first embodiment will be described).

FIG. 9 is a schematic sectional view, taken along the gate length direction, of an exemplary CMOSFET according to the second embodiment.

As shown in FIG. 9, the gate electrode of the p-MOSFET is the same as that shown in FIG. 1 except that a W layer (second layer) 8 is formed on the gate insulating film 5 and a layer (first layer) 7, which has Ru crystal grains and W segregated at Ru grain boundaries, is formed on the second layer 8.

In general, the work function of a gate electrode is determined by that of a material that forms an interface between the gate electrode and a gate insulating film. Therefore, the work function of the gate electrode of the p-MOSFET according to the second embodiment is equal to that of a single W layer. Work functions of gate electrodes formed on an SiO₂ layer and an HfSiON/SiO₂ stack layer were measured after heat treatment processes at 450° C., 800° C., and 1,000° C. in the same manner as in the first embodiment. Measured work functions had p⁺-polysilicon-compatible values (4.8 to 5.2 eV) in both cases. Specifically, in the case of the SiO₂ layer, the work function was 5.10 eV, 5.10 eV, and 4.90 eV at 450° C., 800° C., and 1,000° C., respectively. In the case of the HfSiON/SiO₂ stack layer, the work function was 5.00 eV and 5.20 eV at 450° C. and 1,000° C., respectively.

Since Ru, which is more apt to diffuse into an insulating layer than W (for example, the diffusion coefficient of Ru in SiO₂ is 10-13 cm²/sec whereas that of W in SiO₂ is 10-20 cm²/sec or less) is not present at the interface between the gate electrode and the gate insulating film 5, it is considered that the p-MOSFET according to the second embodiment is more stable in the variation of the insulation performance of the gate insulating film 5 caused by the diffused metal element and the lowering of the long-term reliability caused by the diffused metal element.

In order for the work function of the gate electrode to be identical to that of the material of the second layer 8, the second layer 8 should be of several mono-layers. However, in view of the fact that it is difficult to form such a low second layer 8 as a flat layer, it is desirable that the second layer 8 be higher than or equal to 1 nm. Taking into consideration the fact that the first layer 7 may be higher than or equal to 1 nm as described in the first embodiment, the height of the second layer 8 may be 1 nm or more and less than that of the gate electrode height by 1 nm or more.

Like the first embodiment, the second embodiment can provide a CMOSFET having very thin gate insulating films, because the thickness of the gate insulating films is not increased by heat treatment. It is considered that this is because W segregated at Ru grain boundaries blocks oxygen diffusion paths.

The same advantage is expected even with a structure that a W layer is additionally laid on the first layer 7. Because of high workability and oxidation resistance, this structure is preferable in terms of high compatibility with current manufacturing processes.

An exemplary manufacturing method of the CMOSFET according to the second embodiment will be described below with reference to FIG. 10.

First, device isolation layers 4 are formed selectively on a semiconductor substrate 1 by the STI (shallow trench isolation) method, the LOCOS (local oxidation of silicon) method, or the like.

Then, a p-type semiconductor layer (p-well) 2 and an n-type semiconductor layer (n-well) 3 are formed by ion implantation. A gate insulating film 5 (silicon thermal oxidation film) having 2 nm in thickness is formed on the surfaces of the p-type semiconductor layer 2, the n-type semiconductor layer 3, and the device isolation layers 4. Then, a W layer 8 is deposited by sputtering, whereby a structure of FIG. 10A is obtained.

Then, only the p-type semiconductor layer 2 is covered with a hard mask 13 and an Ru layer 12 is deposited by sputtering, whereby a structure of FIG. 10B is obtained in which the Ru layer 12 is left only on the n-type semiconductor layer 3.

Likewise, only the n-type semiconductor layer 3 is covered with a hard mask 13 and a Si layer 12 is deposited by sputtering, whereby a structure of FIG. 10C is obtained in which the Si layer 14 is left only on the p-type semiconductor layer 2.

Then, after patterning is performed, gate portions are formed by anisotropic etching. Then, portions to become shallow impurity diffusion layers of source/drain regions 9 and 11 of n-type and p-type MIS transistors are formed in a self-aligned manner by implanting arsenic and boron ions using the above lamination gates as masks. Subsequently, after gate side walls 15 are formed on the side surfaces of the lamination gates with an insulating material such as silicon oxide, portions to become deep impurity diffusion layers of the source/drain regions 9 and 11 are formed likewise by ion implantation using the gate sidewalls 15 as masks, whereby a structure of FIG. 10D is obtained.

Then, heat treatment at 800° C. is performed. As a result, in the p-MOSFET, W is diffused from the W layer 8 to the grain boundaries in the Ru layer 12, whereby a first layer 7 is formed in which W exists at the Ru grain boundaries. On the other hand, in the n-MOSFET, Si is diffused from the Si layer 14 to the W layer 8, whereby silicidation occurs and a WSiₓ layer 6 is formed.

Then, heat treatment at 1,000° C. is performed, whereby the impurities are activated and source/drain regions 9 and 11 are formed. In this step, since the gate electrodes of the n-MOSFET and p-MOSFET are heat resistant up to 1,000° C., no change occurs which causes deterioration of the characteristics.

Then, a Ni layer having 20 nm in thickness is evaporated (sputtered) and heat treatment at 400° C. is performed. Non-reacted portions of the metal layer are etched away selectively. As a result, NiSi contact electrodes 10 are formed in a self-aligned manner only on the source/drain electrodes 9 and 11. The structure of FIG. 9 is thus obtained.

### Third Embodiment

A CMOSFET according to a third embodiment will be described below with reference to FIG. 11 (only differences from the first embodiment will be described). Although gate lamination structures corresponding to the first embodiment will be described below, it is a matter of course that gate lamination structures corresponding to the second embodiment are also adoptable.

As shown in FIG. 11, the CMOSFET according to the third embodiment includes an SOI (silicon on insulator) substrate having an insulating layer (SiO₂ layer) 19. The channel portions of the CMOSFET according to the third embodiment are fully depleted and hence the CMOSFET according to the third embodiment is what is called a fully depletion type SOI-CMIS transistor.

The impurity concentrations of the p-type semiconductor layer 2 and the n-type semiconductor layer 3 may be lower than or equal to 10¹⁷ cm⁻³. Also, the thickness of single crystal silicon layers functioning as active regions on the insulating layer 19 may be smaller than or equal to 5 nm.

In general, in fully depletion type SOI devices of the 45-nm technology generation or the generations following it, the work function for obtaining a threshold voltage 0.15 eV, which is required with the gate electrodes of an HP (high performance) device, depends on the thickness of the single crystal silicon layer. Where the thickness of the single crystal silicon layer is 5 nm or less, electrons in the inversion layer occupy high energy levels due to the quantum effect of the thin single crystal silicon layer. Therefore, also in such fully depletion type SOI devices, metal gate electrodes whose work functions are similar to those of the case of using a bulk Si substrate are necessary for the n-type and p-type MOSFETs.

Therefore, in the range that the active single crystal silicon layer is as thin as 5 nm or less and the quantum effect occurs, the structure of FIG. 11 makes it possible to control the threshold voltages of the n-type and p-type MOSFETs to appropriate values. In particular, the thickness of the SOI Si film may be 1.5 to 3 nm for the p-MOSFET and 0.5 to 1 nm for the p-MOSFET.

On the other hand, in fully depletion type SOI devices of the 45-nm technology generation and the generations following it, the work functions required for the gate electrodes of an LSTP (low standby power) device are different from the above-mentioned values and are equal to 4.7 to 5.1 eV (the gate electrode of the n-MOSFET) and 4.2 to 4.4 eV (the gate electrode of the p-MOSFET).

Therefore, the lamination structure of the first layer 7 and the second layer 8 is used for the gate electrode of the n-MOSFET and the WSiₓ layer 6 is used for the p-MOSFET. That is, the threshold voltages can be controlled to appropriate values by making the structures of the gate electrodes of the n-MOSFET and the p-MOSFET opposite to the structures shown in FIG. 11

Although the third embodiment is directed to the SOI structure, the same concept can be applied to an SON (silicon on nothing) structure.

The SOI structure may be manufactured by the bonding method, SIMOX (separation by implanted oxygen), epitaxial layer transfer, etc.

### Fourth Embodiment

A CMOSFET according to a fourth embodiment will be described below with reference to FIG. 12 (only differences from the first embodiment will be described). Although gate lamination structures corresponding to the first embodiment will be described below, it is a matter of course that gate lamination structures corresponding to the second embodiment are also adoptable.

As shown in FIG. 12, the CMOSFET according to the fourth embodiment has fin structures.

An insulating layer (SiO₂ layer) 19 is formed on a semiconductor substrate 1 and fin structures functioning as source/drain portions of transistors are formed on the insulating layer 19. Although in FIG. 12 each fin structure is a lamination structure of a Si layer 20, 21 and a SiN layer 22, the SiN layer 22 may be replaced by an insulating film or omitted.

Gate electrodes are formed so as to cross the respective fin structures, and gate insulating films (SiO₂ films) 5 are formed at contact boundaries therebetween.

Each gate electrode of the n-MOSFET is a WSiₓ layer 6, and each gate electrode of the p-MOSFET has a lamination structure of a first layer 7 (closer to the gate electrode) and a second layer 8.

Although not shown in FIG. 12 for the sake of convenience, the source/drain portions are configured as follows. In the p-type fin, n-type high-concentration impurity regions functioning as a source region and a drain region are formed on both sides of channel regions. In the n-type fin, p-type high-concentration impurity regions functioning as a source region and a drain region are formed on both sides of channel regions.

Each transistor of this structure is what is called a double-gate MIS transistor, that is, a MOSFET in which the channel regions are formed adjacent to the side surfaces of the fin. Where each fin is formed by a single Si layer 20, 21 (i.e., the SiN layer 22 is not used), another channel region is formed adjacent to the upper surface of the fin and a tri-gate MIS transistor is thereby formed.

In the device having the three-dimensional structure according to the fourth embodiment, it is very difficult to obtain a uniform impurity concentration profile in the height direction. In view of this, what is called a Schottky source/drain structure may be employed in which the high impurity concentration region is replaced by Ni silicide or the like.

The CMOSFET even having the above structure is also a fully depletion type device as in the case of the third embodiment. Therefore, where the thickness of the channel portions of the fins is smaller than or equal to 5 nm, because of the quantum effect, metal gate electrodes whose work functions are similar to those of the case of using a bulk Si substrate are necessary for the n-type and p-type MOSFETs. In devices having a three-dimensional structure, ion implantation into doped polysilicon electrodes is very difficult. Therefore, the threshold voltage control using only the gate electrodes including the WSiₓ layer 6, the first layer 7, the second layer 8, etc. is particularly effective.

Although the fourth embodiment is directed to the double-gate MOSFETs having the fin structure, the concept of the fourth embodiment can be applied to other devices having a three-dimensional structure such as a planar double-gate MOSFET and a longitudinal double-gate MOSFET.

### Fifth Embodiment

A CMOSFET according to a fifth embodiment will be described below with reference to FIG. 13 (only differences from the first embodiment will be described). Although gate lamination structures corresponding to the first embodiment will be described below, it is a matter of course that gate lamination structures corresponding to the second embodiment are also adoptable.

As shown in FIG. 13, the CMOSFET according to the fifth embodiment has a segregation Schottky structure.

The n-MOSFET has first impurity segregation source/drain regions (CoSi₂ regions) 23 and the p-MOSFET has second impurity segregation source/drain regions (CoSi₂ regions) 24.

In the p-type semiconductor layer 2, n-type impurity regions of As, for example, having a very steep concentration profile (i.e., shallow regions are doped at a high concentration) exist at the interfaces with the impurity segregation source/drain regions 23. As a result, a large increase in the interface electric field strength caused by As⁺ ions lowers the barrier height and increases the tunnel current due to the image force effect. The barrier height of the Schottky junction is thus lowered.

On the other hand, in the second impurity segregation source/drain regions 24, a large amount of p-type impurity (e.g., B) is segregated in very thin regions at the interfaces with the n-type semiconductor layer 3. As a result, the B at the interfaces modulates the work function of CoSi₂ and thereby lowers the barrier height of the Schottky junction.

Features of a manufacturing method according to the fifth embodiment are as follows.

Before silicidation, impurity ions are implanted and activated, whereby shallow impurity regions are formed in a Si layer. Then, silicidation is performed so as to consume all the thus-formed impurity regions. The impurity is pushed out to the CoSi₂/Si interfaces as snow is shoveled out. The Schottky junctions shown in FIG. 13 are formed in this manner.

Although the embodiments of the invention have been described above, the invention is not limited thereto. Various modifications may be made within the spirit and scope of claims. Further, when practicing the invention, various modifications may be made without departing from the spirit and scope of claims. Still further, various inventions can be made by combining plural constituent elements of the above embodiments as appropriate.

What is claimed is:

1. A semiconductor device comprising:
a first semiconductor layer of a first conductivity type;
a first gate insulating film formed on the first semiconductor layer;
a first gate electrode formed on the first gate insulating film, the first gate electrode comprising:
crystal grains of a first metal consisting of Ru; and
a second metal selected from the group consisting of W, Ni, Mo, Rh, Pd, Re Ir, and Pt, the second metal segregated at a grain boundary between the crystal grains of the first metal; and
first source/drain regions formed in the first semiconductor layer, across the first gate insulating film from each other in a gate length direction of the first gate insulating film.

2. The semiconductor device according to claim 1, wherein:
the first gate electrode comprises:
a first layer comprising:
the crystal grains of the first metal; and
the second metal segregated at the grain boundary between the crystal grains of the first metal; and
a second layer formed on the first layer, the second layer comprising the second metal.

3. The semiconductor device according to claim 2, wherein at least a part of the second metal of the first layer is in contact with the first gate insulating film.

4. The semiconductor device according to claim 2, wherein the first layer is in a range of 1 nm to 25 nm in thickness.

5. The semiconductor device according to claim 1, further comprising an insulating layer disposed under a region including the first gate insulating film and the first source/drain regions and under the first semiconductor layer.

6. The semiconductor device according to claim 2, wherein the content of the second metal in the crystal grain of the first metal is 5% or less.

7. The semiconductor device according to claim 2, wherein the content of the second metal in the crystal grains of the first metal is less than the content of the second metal in a boundary between the first layer and the first gate insulating film.

8. The semiconductor device according to claim 1, wherein the first gate insulating film comprises no second material.

9. The semiconductor device according to claim 1, further comprising:
a second semiconductor layer of a second conductivity type different from the first conductivity type;
a second gate insulating film formed on the second semiconductor layer;
a second gate electrode formed on the second gate insulating film;
second source/drain regions formed in the second semiconductor layer, across the second gate insulating film from each other in a gate length direction of the second gate insulating film; and
a semiconductor substrate formed under the first semiconductor layer and the second semiconductor layer.

10. The semiconductor device according to claim 9, wherein the first conductivity type is an n type and the second conductivity type is a p type.

11. A semiconductor device comprising:
a first semiconductor layer of a first conductivity type;
a first gate insulating film formed on the first semiconductor layer;
a first gate electrode formed on the first gate insulating film, the first gate electrode comprising:
crystal grains of a first metal consisting of Pt; and
a second metal selected from the group consisting of W, Re, Rh, Pd, Ir, and Ru, the second metal segregated at a grain boundary between the crystal grains of the first metal; and
first source/drain regions formed in the first semiconductor layer, across the first gate insulating film from each other in a gate length direction of the first gate insulating film.

12. A semiconductor device comprising:
a first semiconductor layer of a first conductivity type;
a first gate insulating film formed on the first semiconductor layer;
a first gate electrode formed on the first gate insulating film, the first gate electrode comprising:
crystal grains of a first metal consisting of Ir; and
a second metal selected from the group consisting of Re, Rh, Ni, Pd, Pt and Ru, the second metal segregated at a grain boundary between the crystal grains of the first metal; and
first source/drain regions formed in the first semiconductor layer, across the first gate insulating film from each other in a gate length direction of the first gate insulating film.

13. A semiconductor device comprising:
a first semiconductor layer of a first conductivity type;
a first gate insulating film formed on the first semiconductor layer;
a first gate electrode formed on the first gate insulating film, the first gate electrode comprising:
crystal grains of a first metal consisting of Re; and
a second metal selected from the group consisting of Rh, Ni, Pd, Ir, Pt and Ru, the second metal segregated at a grain boundary between the crystal grains of the first metal; and
first source/drain regions formed in the first semiconductor layer, across the first gate insulating film from each other in a gate length direction of the first gate insulating film.

14. A method for manufacturing a semiconductor device, the method comprising:
forming a first gate insulating film on a first semiconductor layer of a first conductivity type;
forming, on the first gate insulating film, a first gate electrode comprising:
a layer comprising crystal grains of a first metal consisting of Ru; and
a layer comprising a second metal selected from the group consisting of W, Ni, Mo, Rh, Pd, Re, Ir, and Pt;
segregating the second metal at a grain boundary between the crystal grains of the first metal; and
forming first source/drain regions in the first semiconductor layer, across the first gate insulating film from each other in a gate length direction of the first gate insulating film.

15. The method according to claim 14, wherein the segregating comprises heating the first insulating film and the first gate electrode.

16. The method according to claim 15, wherein the first insulating film and the first gate electrode are heated at 500 degrees Celsius to 950 degrees Celsius.

17. The method according to claim 16, wherein the first insulating film and the first gate electrode are heated at 750 degrees Celsius to 850 degrees Celsius.

18. The method according to claim 14, further comprising:
forming the first semiconductor layer on a semiconductor substrate;
forming a second semiconductor layer of a second conductivity type on the semiconductor substrate, the second conductivity type different from the first conductivity type;
forming a second gate insulating film on the second semiconductor layer;
forming, on the second gate insulating film, a second gate electrode comprising a layer comprising W and another semiconductor layer;
performing silicidation of the layer comprising W and the another semiconductor layer; and
forming second source/drain regions in the second semiconductor layer, wherein:
the second metal comprises W.
